(19) United States
(12) Patent Application Publication
(10) Pub. No.: US 2026/0215302 A1
(43) Pub. Date: Jul. 23, 2026

(54) CHIP PACKAGE STRUCTURE WITH GLASS SUBSTRATE AND METHOD FOR FORMING THE SAME

(71) Applicant: Taiwan Semiconductor Manufacturing Company, Ltd., Hsinchu (TW)

(72) Inventors: Chien-Fu TSENG, Taipei City (TW); Manikandan ARUMUGAM, Tainan (TW); Han-Yi LU, Hsinchu City (TW); Wei-Cheng WU, Hsinchu City (TW); Der-Chyang YEH, Hsin-Chu (TW)

(73) Assignee: Taiwan Semiconductor Manufacturing Company, Ltd., Hsinchu (TW)

(21) Appl. No.: 19/031,128

(22) Filed: Jan. 17, 2025

(51) Int. Cl. H01L 23/538; H01L 21/56; H01L 21/768; H01L 23/00; H01L 23/15; H01L 23/31; H01L 23/498; H01L 25/065

(52) U.S. Cl. CPC H10W 70/65; H10W 20/056; H10W 70/611; H10W 70/692; H10W 74/01; H10W 74/131; H10W 90/00; H10W 90/401; H10W 72/252; H10W 74/10; H10W 74/15; H10W 90/722; H10W 90/724; H10W 90/734

(57) ABSTRACT

A method for forming a chip package structure is provided. The method includes forming a conductive pillar in a glass substrate. The method includes removing a portion of the glass substrate from a top surface of the glass substrate to form a recess in the glass substrate. The method includes disposing a first chip in the recess. The method includes disposing a second chip over the first chip and the conductive pillar. The method includes removing a bottom portion of the glass substrate to expose the conductive pillar and the first chip.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements.

Dozens or hundreds of integrated circuits are typically manufactured on a single semiconductor wafer. The individual dies are singulated by sawing the integrated circuits along scribe lines. The individual dies are then packaged separately. The semiconductor industry continues to improve the integration density of various electronic components (e.g., transistors, diodes, resistors, capacitors, etc.) by continual reductions in minimum feature size, which allow more components to be integrated into a given area. However, since feature sizes of dies continue to decrease, feature sizes of an interposer substrate for carrying the dies decrease as well. Therefore, it is a challenge to form reliable packages with the dies and the interposer substrate.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A-1G are cross-sectional views of various stages of a process for forming a chip package structure, in accordance with some embodiments.

FIG. 1A-1 is a top view of the chip package structure of FIG. 1A, in accordance with some embodiments.

FIG. 1B-1 is a top view of the chip package structure of FIG. 1B, in accordance with some embodiments.

FIGS. 2A-2B are cross-sectional views of various stages of a process for forming a chip package structure, in accordance with some embodiments.

FIGS. 3A-3C are cross-sectional views of various stages of a process for forming a chip package structure, in accordance with some embodiments.

FIGS. 4A-4E are cross-sectional views of various stages of a process for forming a chip package structure, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. The term “substantially” may be varied in different technologies and be in the deviation range understood by the skilled in the art. For example, the term “substantially” may also relate to 90% of what is specified or higher, such as 95% of what is specified or higher, especially 99% of what is specified or higher, including 100% of what is specified, though the present invention is not limited thereto. Furthermore, terms such as “substantially parallel” or “substantially perpendicular” may be interpreted as not to exclude insignificant deviation from the specified arrangement and may include for example deviations of up to 10°. The word “substantially” does not exclude “completely” e.g. a composition which is “substantially free” from Y may be completely free from Y.

The term “about” may be varied in different technologies and be in the deviation range understood by the skilled in the art. The term “about” in conjunction with a specific distance or size is to be interpreted so as not to exclude insignificant deviation from the specified distance or size. For example, the term “about” may include deviations of up to 10% of what is specified, though the present invention is not limited thereto. The term “about” in relation to a numerical value x may mean x±5 or 10% of what is specified, though the present invention is not limited thereto.

Some embodiments of the disclosure are described. Additional operations can be provided before, during, and/or after the stages described in these embodiments. Some of the stages that are described can be replaced or eliminated for different embodiments. Additional features can be added to the chip package structure. Some of the features described below can be replaced or eliminated for different embodiments. Although some embodiments are discussed with operations performed in a particular order, these operations may be performed in another logical order.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

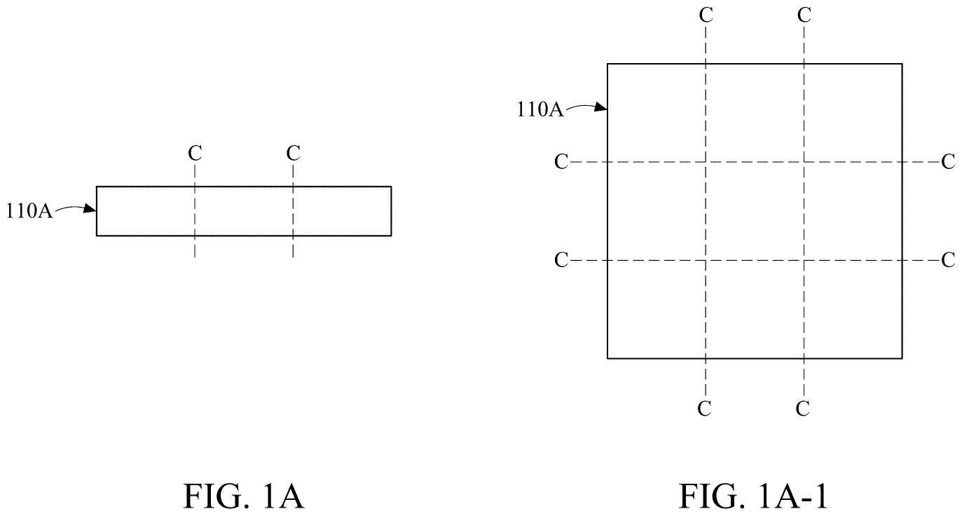

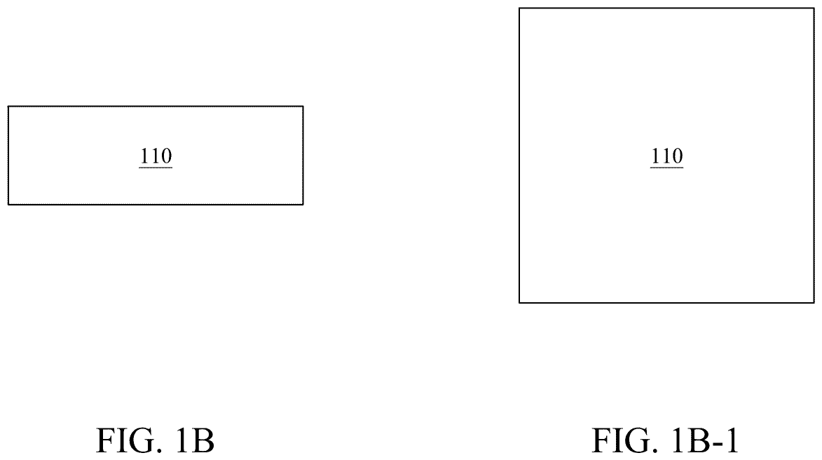

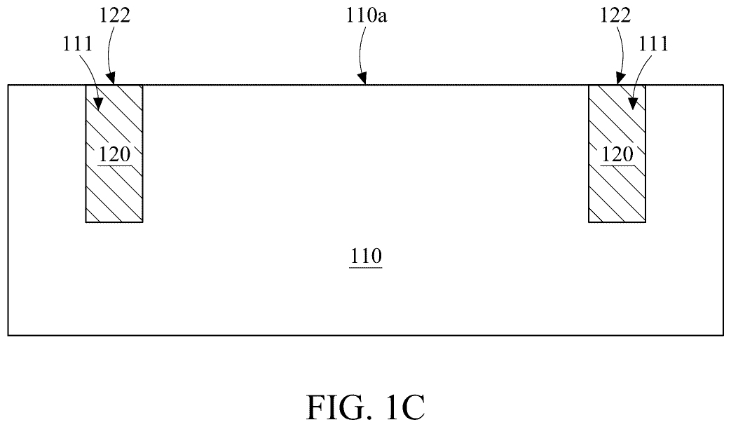

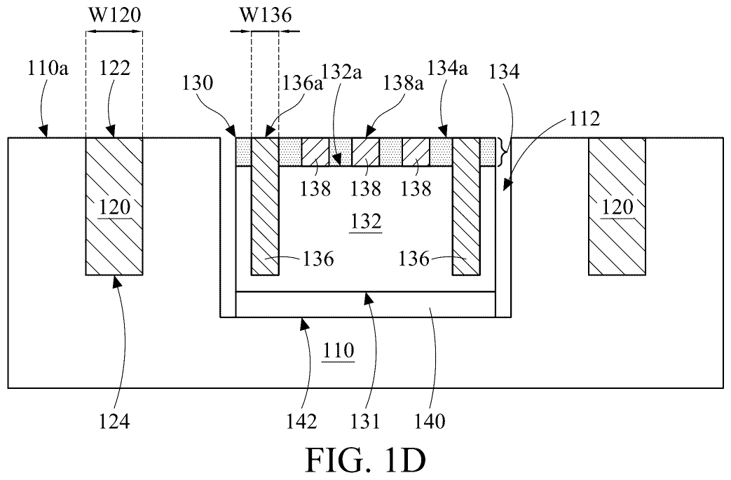

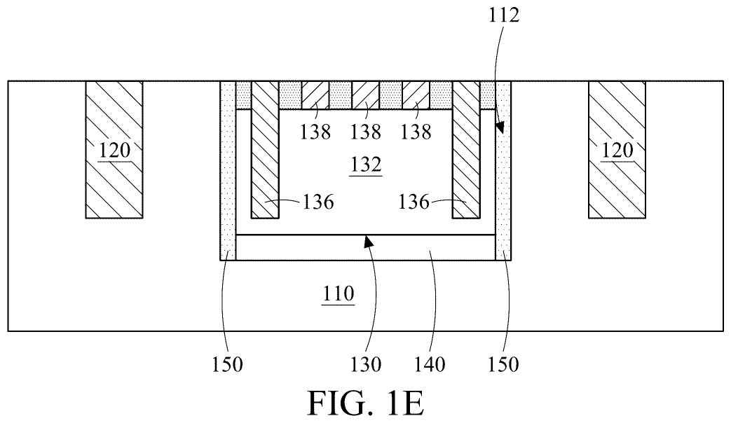

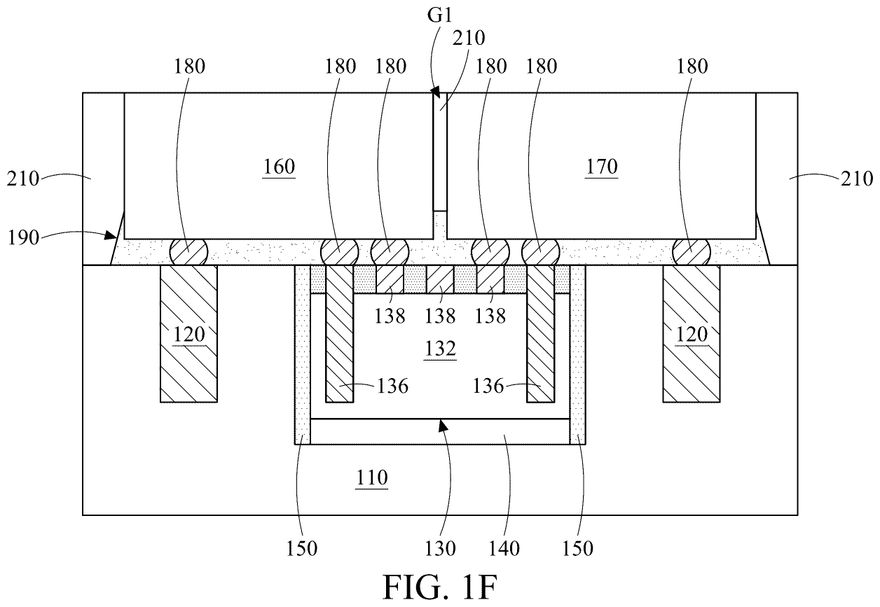

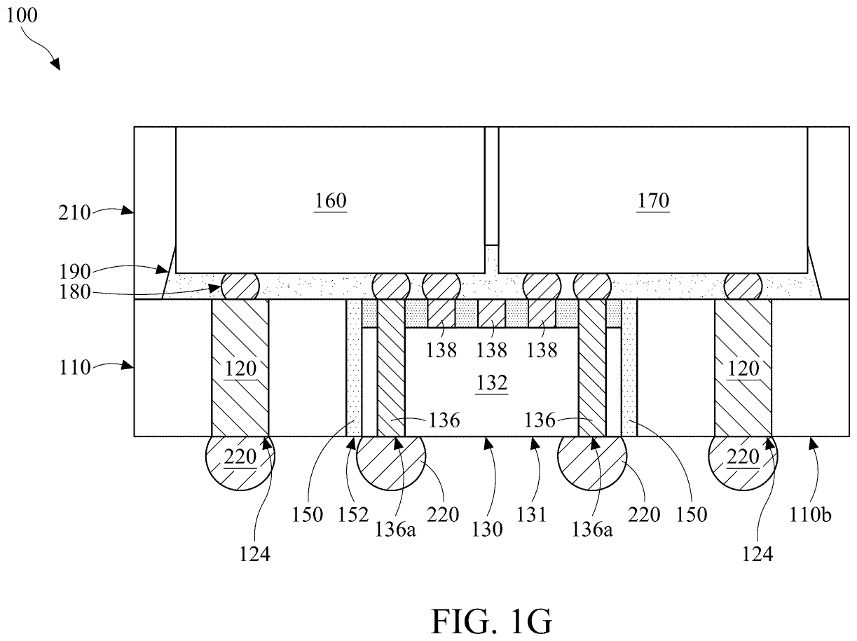

FIGS. 1A-1G are cross-sectional views of various stages of a process for forming a chip package structure, in accordance with some embodiments. FIG. 1A-1 is a top view of the chip package structure of FIG. 1A, in accordance with some embodiments.

As shown in FIGS. 1A and 1A-1, a glass substrate 110A is provided, in accordance with some embodiments. The glass substrate 110A has a square shape, in accordance with some embodiments. The glass substrate 110A is made of silicon oxide, borosilicate glass (BSG), phosphoric silicate glass (PSG), borophosphosilicate glass (BPSG), fluorinated silicate glass (FSG), or a combination thereof, in accordance with some embodiments.

FIG. 1B-1 is a top view of the chip package structure of FIG. 1B, in accordance with some embodiments. As shown in FIG. 1A, 1A-1, 1B, and 1B-1, a cutting process is performed along cutting lines C to cut through the glass substrate 110A so as to form glass substrates 110, in accordance with some embodiments. The glass substrate 110 has a square shape, in accordance with some embodiments. The glass substrate 110 is also referred to as an interposer substrate, in accordance with some embodiments.

Since the glass substrate 110A has a square shape, the glass substrate 110A has a high utilization rate for forming the glass substrate 110 (also having a square shape), in accordance with some embodiments. Therefore, the utilization rate of glass substrate 110A (used to form the interposer substrate) is higher than the utilization rate of silicon wafer (having a circular shape), which greatly reduces the cost of forming the interposer substrate, in accordance with some embodiments.

As shown in FIG. 1C, portions of the glass substrate 110 are removed from a top surface 110a of the glass substrate 110 to form holes 111 in the glass substrate 110, in accordance with some embodiments. The removal process of the portions of the glass substrate 110 includes an etching process such as a laser etching process or a laser modified post chemical treatment (LMCT) etching process, in accordance with some embodiments.

As shown in FIG. 1C, conductive pillars 120 are formed in the holes 111 respectively, in accordance with some embodiments. The top surfaces 122 of the conductive pillars 120 are substantially level with the top surface 110a of the glass substrate 110, in accordance with some embodiments.

The conductive pillars 120 are made of a conductive material, such as metal (e.g., copper, aluminum, gold, silver, tin, or tungsten) or alloys thereof, in accordance with some embodiments.

The conductive pillars 120 are formed using a plating process such as an electrical plating process, in accordance with some embodiments. In some other embodiments, the formation of the conductive pillars 120 includes disposing a metal powder in the holes 111; and reflowing the metal powder. The metal powder is made of tin (Sn) and alloys thereof, in accordance with some embodiments.

As shown in FIG. 1D, a portion of the glass substrate 110 is removed from the top surface 110a of the glass substrate 110 to form a recess 112 in the glass substrate 110, in accordance with some embodiments. The removal process of the portion of the glass substrate 110 includes an etching process such as a laser etching process or a laser modified post chemical treatment (LMCT) etching process, in accordance with some embodiments.

As shown in FIG. 1D, a chip 130 is provided, in accordance with some embodiments. The chip 130 has a substrate 132, a dielectric layer 134, and conductive via structures 136 and 138, in accordance with some embodiments. The dielectric layer 134 is over the substrate 132, in accordance with some embodiments.

The conductive via structures 136 pass through the dielectric layer 134 and penetrate into the substrate 132, in accordance with some embodiments. The width W120 of the conductive pillar 120 is greater than the width W136 of the conductive via structure 136, in accordance with some embodiments. The conductive via structures 138 is over the substrate 132 and in the dielectric layer 134, in accordance with some embodiments.

The substrate 132 includes, for example, a semiconductor substrate. In some embodiments, the substrate 132 is made of an elementary semiconductor material including silicon or germanium in a single crystal structure, a polycrystal structure, or an amorphous structure.

In some other embodiments, the substrate 132 is made of a compound semiconductor, such as silicon carbide, gallium arsenide, gallium phosphide, indium phosphide, indium arsenide, an alloy semiconductor, such as SiGe or GaAsP, or a combination thereof. The substrate 132 may also include multi-layer semiconductors, semiconductor on insulator (SOI) (such as silicon on insulator or germanium on insulator), or a combination thereof.

In some embodiments, the substrate 132 is a device substrate that includes various device elements. In some embodiments, the various device elements are formed in and/or over the substrate 132. The device elements are not shown in figures for the purpose of simplicity and clarity.

Examples of the various device elements include active devices, passive devices, other suitable elements, or a combination thereof. The active devices may include transistors or diodes (not shown) formed at a surface of the substrate 132. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate 132. The isolation features are used to surround active regions and electrically isolate various device elements formed in and/or over the substrate 132 in the active regions. In some embodiments, the isolation features include shallow trench isolation (STI) features, local oxidation of silicon (LOCOS) features, other suitable isolation features, or a combination thereof.

The dielectric layer 134 is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer includes a low-k material or a porous dielectric material having a k-value which is lower than that of silicon oxide, or lower than about 3.0 or about 2.5, in accordance with some embodiments.

The conductive via structures 136 and 138 are electrically connected to the device elements formed in and/or over the substrate 132 in the active regions, in accordance with some embodiments. The conductive via structures 136 and 138 are made of a conductive material, such as metal (e.g., copper, aluminum, gold, silver, tin, or tungsten) or alloys thereof, in accordance with some embodiments.

As shown in FIG. 1D, an adhesive layer 140 is formed over a bottom surface 131 of the chip 130, in accordance with some embodiments. The adhesive layer 140 is made of a polymer material, in accordance with some embodiments.

As shown in FIG. 1D, the chip 130 is bonded to the glass substrate 110 through the adhesive layer 140, in accordance with some embodiments. The chip 130 is in the recess 112 of the glass substrate 110, in accordance with some embodiments. The chip 130 is spaced apart from the glass substrate 110, in accordance with some embodiments.

The top surfaces 110a, 122, 134a, 136a, and 138a of the glass substrate 110, the conductive pillars 120, the dielectric layer 134, and the conductive via structures 136 and 138 are substantially level with each other, in accordance with some embodiments. The bottom surface 142 of the adhesive layer 140 is lower than the bottom surface 124 of the conductive pillar 120, in accordance with some embodiments.

As shown in FIG. 1E, a molding layer 150 is formed in the recess 112 of the glass substrate 110, in accordance with some embodiments. The molding layer 150 surrounds the chip 130, in accordance with some embodiments. The molding layer 150 is made of an insulating material, such as a polymer material (e.g., epoxy), in accordance with some embodiments.

As shown in FIG. 1F, chips 160 and 170 are provided, in accordance with some embodiments. The chip 160 includes a substrate, a dielectric layer, and wiring layers (not shown), in accordance with some embodiments. The dielectric layer is over the substrate, in accordance with some embodiments. The wiring layers are in the dielectric layer, in accordance with some embodiments.

The substrate includes, for example, a semiconductor substrate. In some embodiments, the substrate is made of an elementary semiconductor material including silicon or germanium in a single crystal structure, a polycrystal structure, or an amorphous structure.

In some other embodiments, the substrate is made of a compound semiconductor, such as silicon carbide, gallium arsenide, gallium phosphide, indium phosphide, indium arsenide, an alloy semiconductor, such as SiGe or GaAsP, or a combination thereof. The substrate may also include multi-layer semiconductors, semiconductor on insulator (SOI) (such as silicon on insulator or germanium on insulator), or a combination thereof.

In some embodiments, the substrate is a device substrate that includes various device elements. In some embodiments, the various device elements are formed in and/or over the substrate. The device elements are not shown in figures for the purpose of simplicity and clarity.

Examples of the various device elements include active devices, passive devices, other suitable elements, or a combination thereof. The active devices may include transistors or diodes (not shown) formed at a surface of the substrate. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate. The isolation features are used to surround active regions and electrically isolate various device elements formed in and/or over the substrate in the active regions. In some embodiments, the isolation features include shallow trench isolation (STI) features, local oxidation of silicon (LOCOS) features, other suitable isolation features, or a combination thereof.

The dielectric layer is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer includes a low-k material or a porous dielectric material having a k-value which is lower than that of silicon oxide, or lower than about 3.0 or about 2.5, in accordance with some embodiments.

The wiring layers are electrically connected to the device elements formed in and/or over the substrate in the active regions, in accordance with some embodiments. The wiring layers are made of a conductive material, such as metal (e.g., copper, aluminum, gold, silver, tin, or tungsten) or alloys thereof, in accordance with some embodiments.

The chip 170 includes a substrate, a dielectric layer, and wiring layers (not shown), in accordance with some embodiments. The dielectric layer is over the substrate, in accordance with some embodiments. The wiring layers are in the dielectric layer, in accordance with some embodiments.

The substrate includes, for example, a semiconductor substrate. In some embodiments, the substrate is made of an elementary semiconductor material including silicon or germanium in a single crystal structure, a polycrystal structure, or an amorphous structure.

In some other embodiments, the substrate is made of a compound semiconductor, such as silicon carbide, gallium arsenide, gallium phosphide, indium phosphide, indium arsenide, an alloy semiconductor, such as SiGe or GaAsP, or a combination thereof. The substrate may also include multi-layer semiconductors, semiconductor on insulator (SOI) (such as silicon on insulator or germanium on insulator), or a combination thereof.

In some embodiments, the substrate is a device substrate that includes various device elements. In some embodiments, the various device elements are formed in and/or over the substrate. The device elements are not shown in figures for the purpose of simplicity and clarity.

Examples of the various device elements include active devices, passive devices, other suitable elements, or a combination thereof. The active devices may include transistors or diodes (not shown) formed at a surface of the substrate. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate. The isolation features are used to surround active regions and electrically isolate various device elements formed in and/or over the substrate in the active regions. In some embodiments, the isolation features include shallow trench isolation (STI) features, local oxidation of silicon (LOCOS) features, other suitable isolation features, or a combination thereof.

The dielectric layer is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer includes a low-k material or a porous dielectric material having a k-value which is lower than that of silicon oxide, or lower than about 3.0 or about 2.5, in accordance with some embodiments.

The wiring layers are electrically connected to the device elements formed in and/or over the substrate in the active regions, in accordance with some embodiments. The wiring layers are made of a conductive material, such as metal (e.g., copper, aluminum, gold, silver, tin, or tungsten) or alloys thereof, in accordance with some embodiments.

As shown in FIG. 1F, chips 160 and 170 are bonded to the conductive via structures 136 and 138 of the chip 130 and the conductive pillars 120 through conductive bumps 180, in accordance with some embodiments.

The conductive bumps 180 are made of a conductive material, such as a tin-based alloy, in accordance with some embodiments. In some other embodiments, the conductive bumps 180 are made of a conductive material, such as metal (e.g., copper, aluminum, gold, silver, or tungsten) or alloys thereof, in accordance with some embodiments.

As shown in FIG. 1F, an underfill layer 190 is formed between the chips 130, 160, and 170, between the conductive pillars 120 and the chips 160 and 170, between the glass substrate 110 and the chips 160 and 170, and between the molding layer 150 and the chips 160 and 170, in accordance with some embodiments.

The underfill layer 190 extends into a gap G1 between the chips 160 and 170, in accordance with some embodiments. The underfill layer 190 is made of an insulating material, such as a polymer material, in accordance with some embodiments.

As shown in FIG. 1F, a molding layer 210 is formed over the glass substrate 110, the conductive pillars 120, the chip 130, and the molding layer 150, in accordance with some embodiments. The molding layer 210 surrounds the chips 160 and 170, in accordance with some embodiments.

The molding layer 210 surrounds the conductive bumps 180 and the underfill layer 190, in accordance with some embodiments. The molding layer 210 is made of an insulating material, such as a polymer material (e.g., epoxy), in accordance with some embodiments.

As shown in FIG. 1G, a bottom portion of the glass substrate 110, the adhesive layer 140, a bottom portion of the molding layer 150, bottom portions of the conductive pillars 120, and a bottom portion of the chip 130 are removed to expose the bottom surfaces 124 of the conductive pillars 120, the bottom surface 131 of the chip 130, and the bottom surface 152 of the molding layer 150, in accordance with some embodiments.

The bottom surfaces 124 of the conductive pillars 120, the bottom surface 131 of the chip 130, and the bottom surface 152 of the molding layer 150 are substantially level with each other, in accordance with some embodiments. The bottom surfaces 136a of the conductive via structures 136 are also exposed, in accordance with some embodiments.

The conductive pillars 120 pass through the glass substrate 110, in accordance with some embodiments. The conductive via structures 136 pass through the substrate 132, in accordance with some embodiments. The removal process includes a planarization process such as a chemical mechanical polishing (CMP) process, in accordance with some embodiments.

As shown in FIG. 1G, conductive bumps 220 are formed over the bottom surfaces 124 of the conductive pillars 120 and the bottom surfaces 136a of the conductive via structures 136, in accordance with some embodiments. The conductive bumps 220 are made of a conductive material, such as a tin-based alloy, in accordance with some embodiments.

In some other embodiments, the conductive bumps 220 are made of a conductive material, such as metal (e.g., copper, aluminum, gold, silver, or tungsten) or alloys thereof, in accordance with some embodiments. In this step, a chip package structure 100 is substantially formed, in accordance with some embodiments.

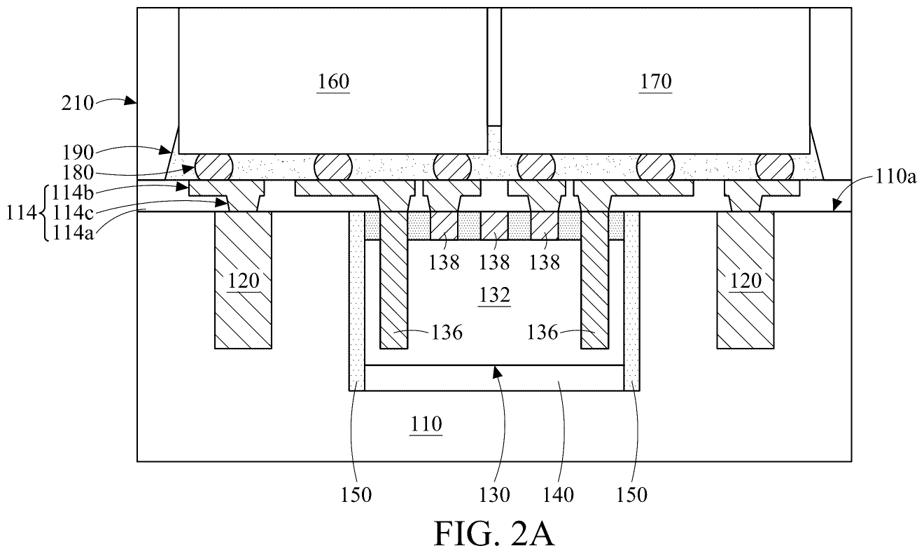

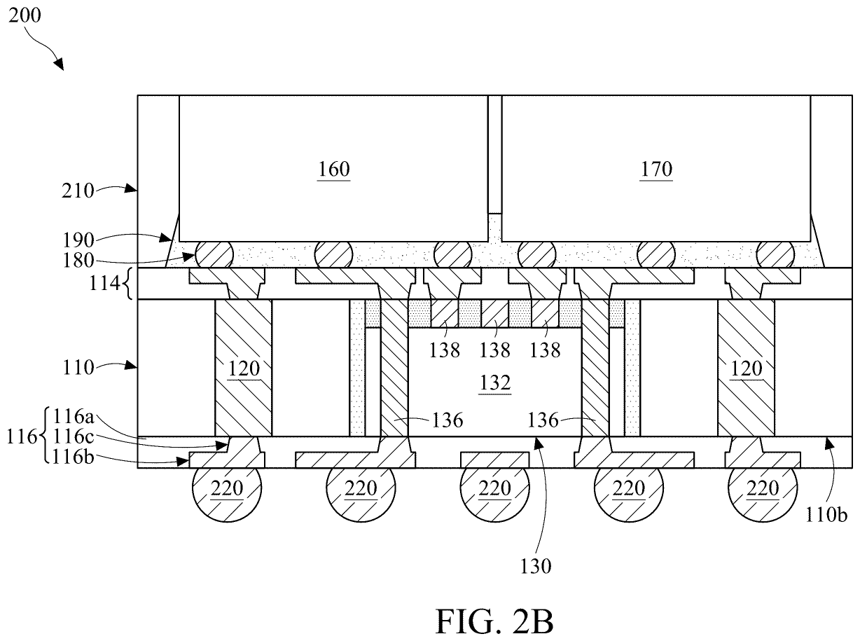

FIGS. 2A-2B are cross-sectional views of various stages of a process for forming a chip package structure, in accordance with some embodiments. As shown in FIG. 2A, after the step of FIG. 1E is performed, a redistribution layer 114 is formed over the top surface 110a of the glass substrate 110, the conductive pillars 120, the chip 130, and the molding layer 150, in accordance with some embodiments.

The redistribution layer 114 includes a dielectric layer 114a, a wiring layer 114b, and conductive vias 114c, in accordance with some embodiments. The wiring layer 114b and the conductive vias 114c are in the dielectric layer 114a, in accordance with some embodiments. The conductive vias 114c are electrically connected between the wiring layer 114b, the conductive pillars 120, and the conductive via structures 136 and 138, in accordance with some embodiments.

The dielectric layer 114a is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer 114a includes a low-k material or a porous dielectric material having a k-value which is lower than that of silicon oxide, or lower than about 3.0 or about 2.5, in accordance with some embodiments.

The wiring layer 114b is made of a conductive material, such as metal (e.g., copper, aluminum, gold, silver, tin, or tungsten) or alloys thereof, in accordance with some embodiments. The conductive vias 114c are made of a conductive material, such as metal (e.g., copper, aluminum, gold, silver, tin, or tungsten) or alloys thereof, in accordance with some embodiments.

Thereafter, as shown in FIG. 2A, the step of FIG. 1F is performed to form the chips 160 and 170, the conductive bumps 180, the underfill layer 190, and the molding layer 210, in accordance with some embodiments. The conductive bumps 180 are electrically connected between the chips 160 and 170 and the wiring layer 114b, in accordance with some embodiments.

The conductive pillars 120 and the chip 130 are electrically connected to the chips 160 and 170 through the redistribution layer 114, in accordance with some embodiments. The conductive bumps 180 are electrically connected to and vertically misaligned with the corresponding conductive pillars 120, which prevents the stress generated by the conductive pillars 120 from being transferred vertically to the conductive bumps 180, in accordance with some embodiments. Therefore, the yield of the conductive bumps 180 is improved, in accordance with some embodiments.

The conductive bumps 180 are electrically connected to and vertically misaligned with the corresponding conductive via structures 136, which prevents the stress generated by the conductive via structures 136 from being transferred vertically to the conductive bumps 180, in accordance with some embodiments. Therefore, the yield of the conductive bumps 180 is improved, in accordance with some embodiments.

As shown in FIG. 2B, after the step of FIG. 1G is performed to remove the bottom portion of the glass substrate 110, the adhesive layer 140, the bottom portion of the molding layer 150, the bottom portions of the conductive pillars 120, and the bottom portion of the chip 130, a redistribution layer 116 is formed over the bottom surface 110b of the glass substrate 110, the conductive pillars 120, the chip 130, and the molding layer 150, in accordance with some embodiments.

The redistribution layer 116 includes a dielectric layer 116a, a wiring layer 116b, and conductive vias 116c, in accordance with some embodiments. The wiring layer 116b and the conductive vias 116c are in the dielectric layer 116a, in accordance with some embodiments. The conductive vias 116c are electrically connected between the wiring layer 116b, the conductive pillars 120, and the conductive via structures 136, in accordance with some embodiments.

The dielectric layer 116a is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer 116a includes a low-k material or a porous dielectric material having a k-value which is lower than that of silicon oxide, or lower than about 3.0 or about 2.5, in accordance with some embodiments.

The wiring layer 116b is made of a conductive material, such as metal (e.g., copper, aluminum, gold, silver, tin, or tungsten) or alloys thereof, in accordance with some embodiments. The conductive vias 116c are made of a conductive material, such as metal (e.g., copper, aluminum, gold, silver, tin, or tungsten) or alloys thereof, in accordance with some embodiments.

Thereafter, as shown in FIG. 2B, the step of FIG. 1G is performed to form the conductive bumps 220 over the wiring layer 116b, in accordance with some embodiments. In this step, a chip package structure 200 is substantially formed, in accordance with some embodiments.

The conductive bumps 220 are electrically connected to and vertically misaligned with the corresponding conductive pillars 120, which prevents the stress generated by the conductive pillars 120 from being transferred vertically to the conductive bumps 220, in accordance with some embodiments. Therefore, the yield of the conductive bumps 220 is improved, in accordance with some embodiments.

The conductive bumps 220 are electrically connected to and vertically misaligned with the corresponding conductive via structures 136, which prevents the stress generated by the conductive via structures 136 from being transferred vertically to the conductive bumps 220, in accordance with some embodiments. Therefore, the yield of the conductive bumps 220 is improved, in accordance with some embodiments.

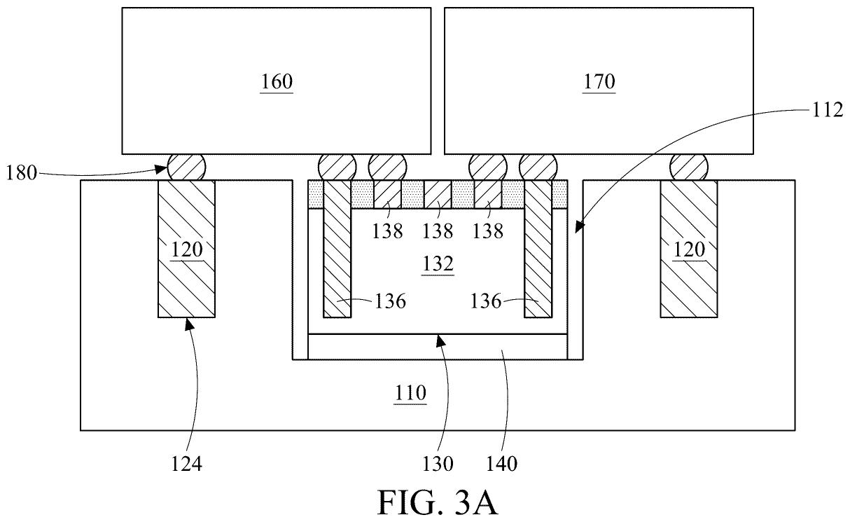

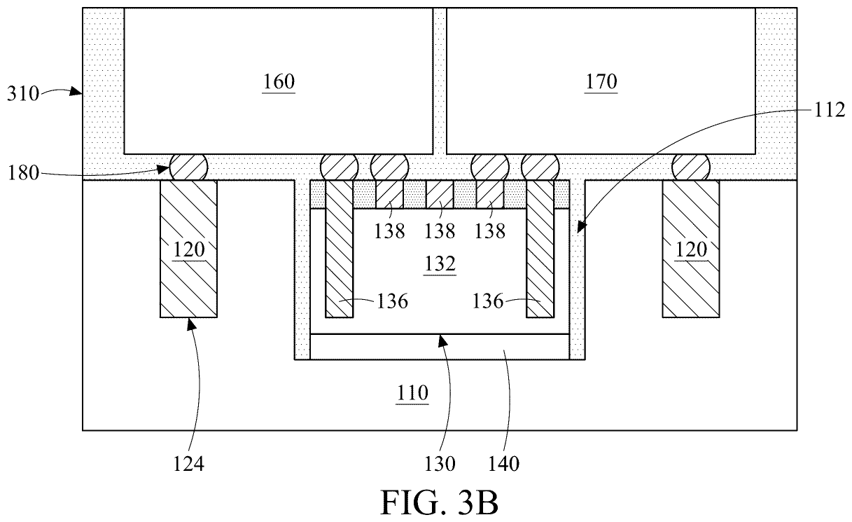

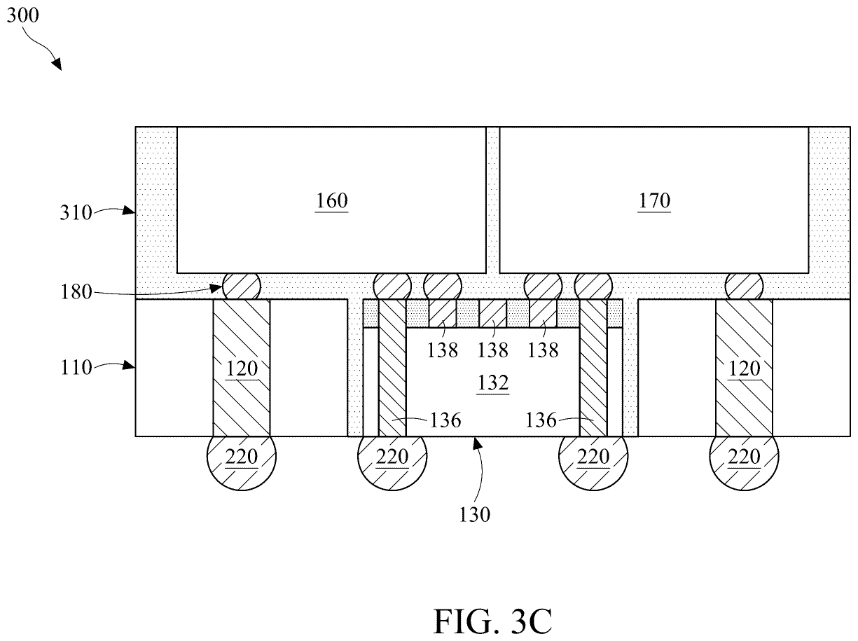

FIGS. 3A-3C are cross-sectional views of various stages of a process for forming a chip package structure, in accordance with some embodiments. As shown in FIG. 3A, after the step of FIG. 1D is performed, the step of FIG. 1F is performed to bond the chips 160 and 170 to the conductive via structures 136 and 138 of the chip 130 and the conductive pillars 120 through the conductive bumps 180, in accordance with some embodiments.

As shown in FIG. 3B, a molding layer 310 is formed over the glass substrate 110 and in the recess 112, in accordance with some embodiments. The molding layer 310 surrounds the chips 130, 160, and 170, in accordance with some embodiments. The molding layer 310 is made of an insulating material, such as a polymer material (e.g., epoxy), in accordance with some embodiments.

As shown in FIG. 3C, the step of FIG. 1G is performed to remove the bottom portion of the glass substrate 110, the adhesive layer 140, the bottom portion of the molding layer 310, the bottom portions of the conductive pillars 120, and the bottom portion of the chip 130, and to form the conductive bumps 220, in accordance with some embodiments. In this step, a chip package structure 300 is substantially formed, in accordance with some embodiments.

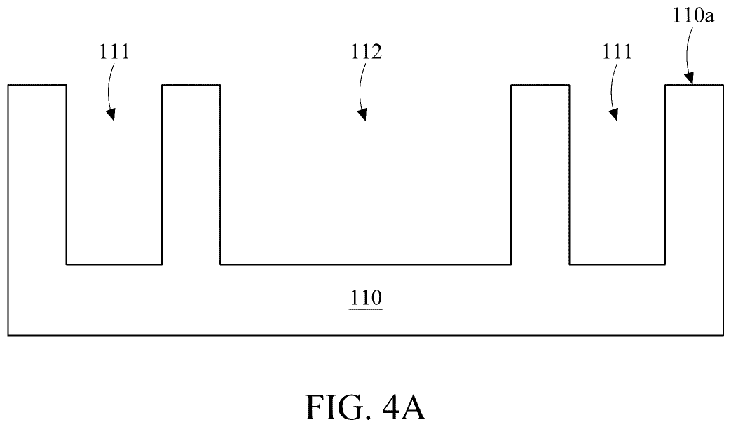

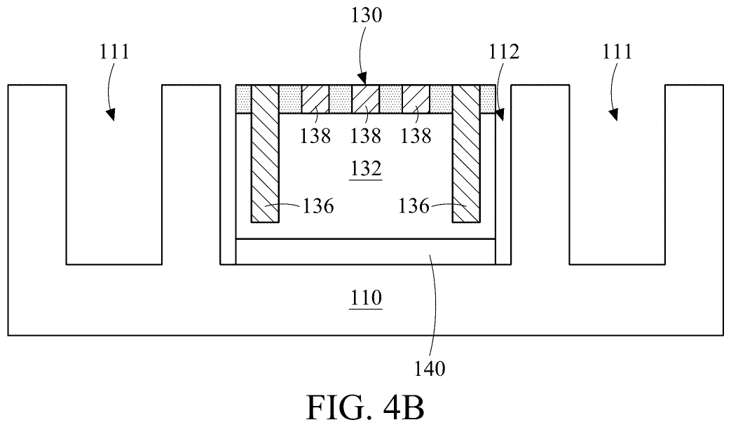

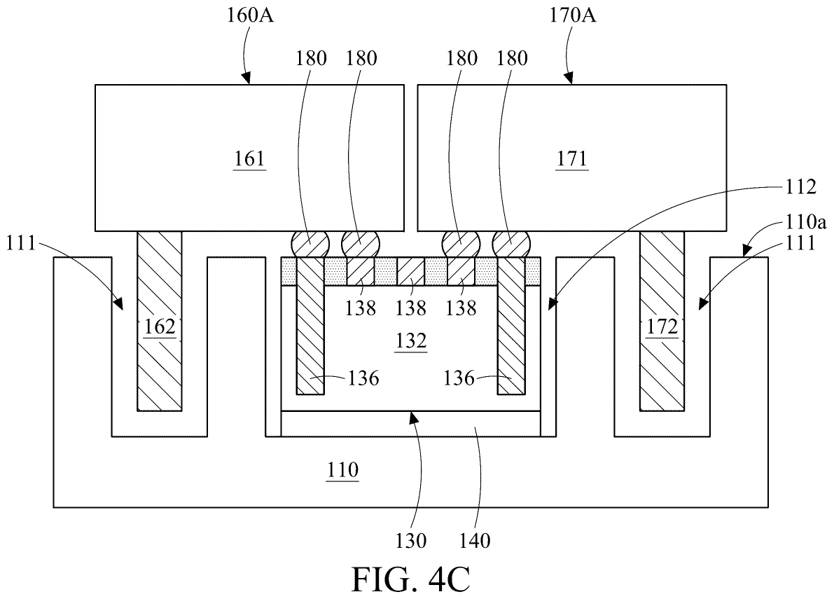

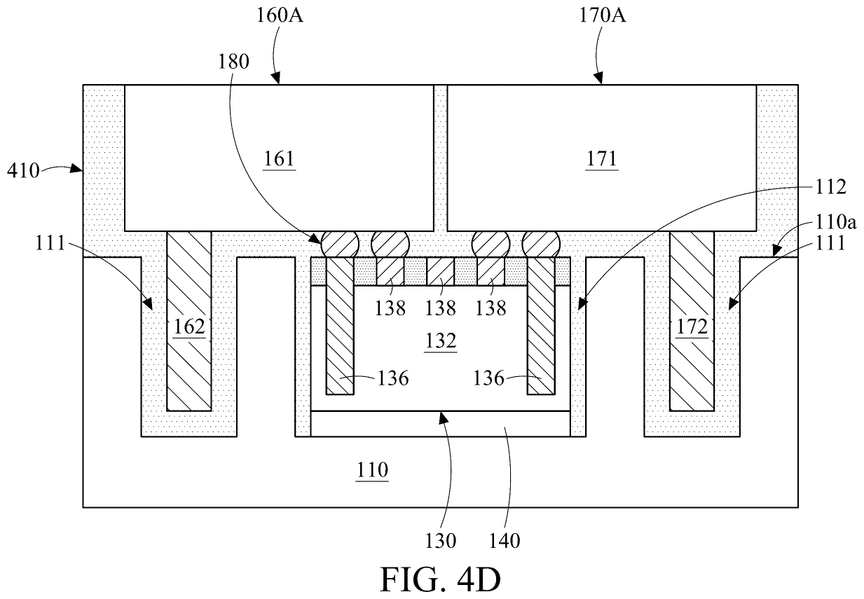

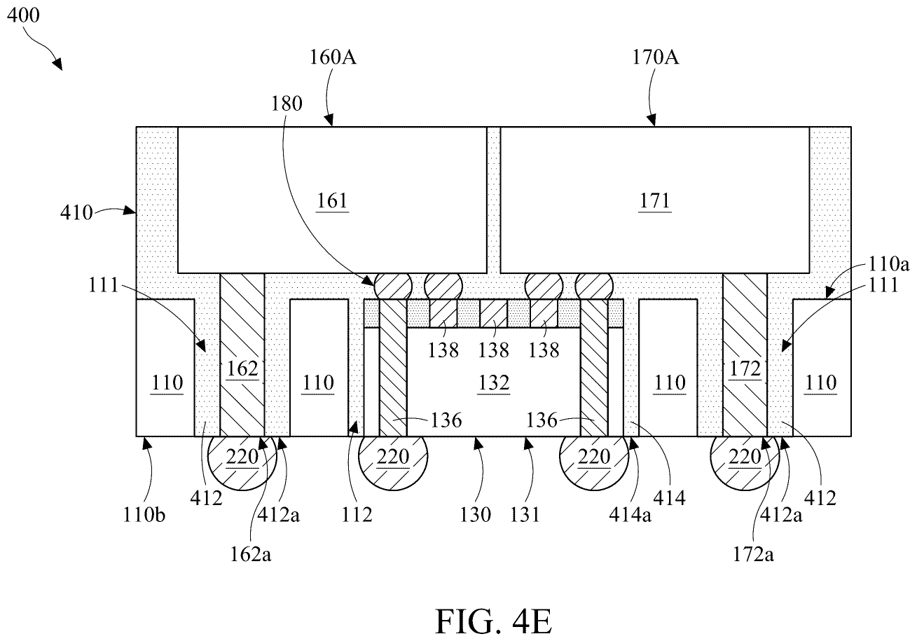

FIGS. 4A-4E are cross-sectional views of various stages of a process for forming a chip package structure, in accordance with some embodiments. As shown in FIG. 4A, a glass substrate 110 is provided, in accordance with some embodiments. The glass substrate 110 has holes 111 and a recess 112, in accordance with some embodiments.

As shown in FIG. 4B, a chip 130 is disposed in the recess 112 of the glass substrate 110, in accordance with some embodiments. The chip 130 is bonded to the glass substrate 110 through the adhesive layer 140, in accordance with some embodiments.

As shown in FIG. 4C, chips 160A and 170A are provided, in accordance with some embodiments. The chip 160A includes a main portion 161 and long conductive pillars 162, in accordance with some embodiments. For the sake of simplicity, FIG. 4C only shows one of the long conductive pillars 162, in accordance with some embodiments.

The main portion 161 includes a substrate, a dielectric layer, and wiring layers (not shown), in accordance with some embodiments. The dielectric layer is over the substrate, in accordance with some embodiments. The wiring layers are in the dielectric layer, in accordance with some embodiments.

The substrate includes, for example, a semiconductor substrate. In some embodiments, the substrate is made of an elementary semiconductor material including silicon or germanium in a single crystal structure, a polycrystal structure, or an amorphous structure.

In some other embodiments, the substrate is made of a compound semiconductor, such as silicon carbide, gallium arsenide, gallium phosphide, indium phosphide, indium arsenide, an alloy semiconductor, such as SiGe or GaAsP, or a combination thereof. The substrate may also include multi-layer semiconductors, semiconductor on insulator (SOI) (such as silicon on insulator or germanium on insulator), or a combination thereof.

In some embodiments, the substrate is a device substrate that includes various device elements. In some embodiments, the various device elements are formed in and/or over the substrate. The device elements are not shown in figures for the purpose of simplicity and clarity.

Examples of the various device elements include active devices, passive devices, other suitable elements, or a combination thereof. The active devices may include transistors or diodes (not shown) formed at a surface of the substrate. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate. The isolation features are used to surround active regions and electrically isolate various device elements formed in and/or over the substrate in the active regions. In some embodiments, the isolation features include shallow trench isolation (STI) features, local oxidation of silicon (LOCOS) features, other suitable isolation features, or a combination thereof.

The dielectric layer is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer includes a low-k material or a porous dielectric material having a k-value which is lower than that of silicon oxide, or lower than about 3.0 or about 2.5, in accordance with some embodiments.

The wiring layers are electrically connected to the device elements formed in and/or over the substrate in the active regions, in accordance with some embodiments. The long conductive pillars 162 are over the main portion 161 and connected to the wiring layers, in accordance with some embodiments.

The wiring layers are made of a conductive material, such as metal (e.g., copper, aluminum, gold, silver, tin, or tungsten) or alloys thereof, in accordance with some embodiments. The long conductive pillars 162 are made of a conductive material, such as metal (e.g., copper, aluminum, gold, silver, tin, or tungsten) or alloys thereof, in accordance with some embodiments.

The chip 170A includes a main portion 171 and long conductive pillars 172, in accordance with some embodiments. For the sake of simplicity, FIG. 4C only shows one of the long conductive pillars 172, in accordance with some embodiments.

The main portion 171 includes a substrate, a dielectric layer, and wiring layers (not shown), in accordance with some embodiments. The dielectric layer is over the substrate, in accordance with some embodiments. The wiring layers are in the dielectric layer, in accordance with some embodiments.

The substrate includes, for example, a semiconductor substrate. In some embodiments, the substrate is made of an elementary semiconductor material including silicon or germanium in a single crystal structure, a polycrystal structure, or an amorphous structure.

In some other embodiments, the substrate is made of a compound semiconductor, such as silicon carbide, gallium arsenide, gallium phosphide, indium phosphide, indium arsenide, an alloy semiconductor, such as SiGe or GaAsP, or a combination thereof. The substrate may also include multi-layer semiconductors, semiconductor on insulator (SOI) (such as silicon on insulator or germanium on insulator), or a combination thereof.

In some embodiments, the substrate is a device substrate that includes various device elements. In some embodiments, the various device elements are formed in and/or over the substrate. The device elements are not shown in figures for the purpose of simplicity and clarity.

Examples of the various device elements include active devices, passive devices, other suitable elements, or a combination thereof. The active devices may include transistors or diodes (not shown) formed at a surface of the substrate. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate. The isolation features are used to surround active regions and electrically isolate various device elements formed in and/or over the substrate in the active regions. In some embodiments, the isolation features include shallow trench isolation (STI) features, local oxidation of silicon (LOCOS) features, other suitable isolation features, or a combination thereof.

The dielectric layer is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer includes a low-k material or a porous dielectric material having a k-value which is lower than that of silicon oxide, or lower than about 3.0 or about 2.5, in accordance with some embodiments.

The wiring layers are electrically connected to the device elements formed in and/or over the substrate in the active regions, in accordance with some embodiments. The long conductive pillars 172 are over the main portion 171 and connected to the wiring layers, in accordance with some embodiments.

The wiring layers are made of a conductive material, such as metal (e.g., copper, aluminum, gold, silver, tin, or tungsten) or alloys thereof, in accordance with some embodiments. The long conductive pillars 172 are made of a conductive material, such as metal (e.g., copper, aluminum, gold, silver, tin, or tungsten) or alloys thereof, in accordance with some embodiments.

As shown in FIG. 4C, the chips 160A and 170A are bonded to the chip 130 through the conductive bumps 180, in accordance with some embodiments. The long conductive pillars 162 and 172 are in the holes 111 respectively, in accordance with some embodiments. The long conductive pillars 162 and 172 are spaced apart from the glass substrate 110, in accordance with some embodiments.

As shown in FIG. 4D, a molding layer 410 is formed over the glass substrate 110 and in the recess 112 and the holes 111, in accordance with some embodiments. The molding layer 410 surrounds the chips 130, 160A, and 170A and the adhesive layer 140, in accordance with some embodiments.

The molding layer 410 surrounds the long conductive pillars 162 and 172, in accordance with some embodiments. The molding layer 410 separates the long conductive pillars 162 and 172 from the glass substrate 110, in accordance with some embodiments. The molding layer 410 is made of an insulating material, such as a polymer material (e.g., epoxy), in accordance with some embodiments.

As shown in FIG. 4E, the step of FIG. 1G is performed to remove the bottom portion of the glass substrate 110, the adhesive layer 140, the bottom portion of the molding layer 410, the bottom portions of the long conductive pillars 162 and 172, and the bottom portion of the chip 130, and to form the conductive bumps 220, in accordance with some embodiments. In this step, a chip package structure 400 is substantially formed, in accordance with some embodiments.

The molding layer 410 has portions 412 and 414, in accordance with some embodiments. The portions 412 are in the holes 111, in accordance with some embodiments. The portion 414 is in the recess 112, in accordance with some embodiments. The bottom surface 412a of the portion 412 and the bottom surface 414a of the portion 414 are exposed, in accordance with some embodiments.

The bottom surfaces 412a, 414a, 162a, 172a, and 131 of the portions 412 and 414, the long conductive pillars 162 and 172, and the chip 130 are substantially level with each other, in accordance with some embodiments. The conductive pillars 162 and 172 protrude from the top surface 110a of the glass substrate 110, in accordance with some embodiments.

Since the chips 160A and 170A have the long conductive pillars 162 and 172, there is no need to form the conductive pillars 120 of the chip package structure 100, thereby simplifying the formation process of the chip packaging structure 400, in accordance with some embodiments.

Processes and materials for forming the chip packaging structures 200, 300, and 400 may be similar to, or the same as, those for forming the chip packaging structure 100 described above. Elements designated by the same or similar reference numbers as those in FIGS. 1A to 4E have the same or similar structures and the materials. Therefore, the detailed descriptions thereof will not be repeated herein.

In accordance with some embodiments, chip package structures and methods for forming the same are provided. The methods (for forming the chip package structure) form a chip package structure having a glass interposer substrate. The glass interposer substrate is formed by cutting a glass substrate. Since both the glass substrate and the glass interposer substrate are square, the utilization rate of the glass substrate to form the glass interposer substrate is high, which greatly reduces the cost of forming the glass interposer substrate.

In accordance with some embodiments, a method for forming a chip package structure is provided. The method includes forming a conductive pillar in a glass substrate. The method includes removing a portion of the glass substrate from a top surface of the glass substrate to form a recess in the glass substrate. The method includes disposing a first chip in the recess. The method includes disposing a second chip over the first chip and the conductive pillar. The method includes removing a bottom portion of the glass substrate to expose the conductive pillar and the first chip.

In accordance with some embodiments, a method for forming a chip package structure is provided. The method includes providing a glass substrate having a hole and a recess. The method includes disposing a first chip in the recess. The method includes bonding a second chip to the first chip. The second chip includes a main portion and a conductive pillar connected to the main portion, and the conductive pillar is in the hole after the second chip is bonded to the first chip. The method includes removing a bottom portion of the glass substrate to expose the conductive pillar and the first chip.

In accordance with some embodiments, a chip package structure is provided. The chip package structure includes a glass substrate. The chip package structure includes a conductive pillar in the glass substrate. The chip package structure includes a first chip in the glass substrate adjacent to the conductive pillar. The chip package structure includes a second chip over the first chip.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a chip package structure, comprising:
forming a conductive pillar in a glass substrate;
removing a portion of the glass substrate from a top surface of the glass substrate to form a recess in the glass substrate;
disposing a first chip in the recess;
disposing a second chip over the first chip and the conductive pillar; and
removing a bottom portion of the glass substrate to expose the conductive pillar and the first chip.

2. The method for forming the chip package structure as claimed in claim 1, further comprising:
forming a first molding layer in the recess after the first chip is disposed in the recess, wherein the first molding layer surrounds the first chip.

3. The method for forming the chip package structure as claimed in claim 2, further comprising:
forming a second molding layer over the glass substrate, the conductive pillar, the first chip, and the first molding layer, wherein the second molding layer surrounds the second chip.

4. The method for forming the chip package structure as claimed in claim 2, further comprising:
forming an underfill layer between the first chip and the second chip, between the conductive pillar and the second chip, between the glass substrate and the second chip, and between the first molding layer and the second chip.

5. The method for forming the chip package structure as claimed in claim 1, further comprising:
forming conductive bumps over a first bottom surface of the conductive pillar and a second bottom surface of the first chip after the bottom portion of the glass substrate is removed.

6. The method for forming the chip package structure as claimed in claim 1, further comprising:
forming an adhesive layer over a first bottom surface of the first chip before the first chip is disposed in the recess, wherein the first chip is bonded to the glass substrate through the adhesive layer, and the removing of the bottom portion of the glass substrate further removes the adhesive layer.

7. The method for forming the chip package structure as claimed in claim 6, wherein a second bottom surface of the adhesive layer is lower than a third bottom surface of the conductive pillar after the first chip is disposed in the recess and before the bottom portion of the glass substrate is removed.

8. The method for forming the chip package structure as claimed in claim 1, wherein the first chip has a substrate, a first conductive via structure, and a second conductive via structure, the first conductive via structure penetrates into the substrate, the second conductive via structure is over the substrate, and a bottom surface of the first conductive via structure is exposed after the bottom portion of the glass substrate is removed.

9. The method for forming the chip package structure as claimed in claim 1, further comprising:
forming a molding layer in the recess and over the glass substrate after the second chip is disposed over the first chip and the conductive pillar, wherein the molding layer surrounds the first chip and the second chip.

10. The method for forming the chip package structure as claimed in claim 1, further comprising:
forming a redistribution layer over the top surface of the glass substrate, the conductive pillar, and the first chip before the second chip is disposed over the first chip and the conductive pillar.

11. A method for forming a chip package structure, comprising:
providing a glass substrate having a hole and a recess;
disposing a first chip in the recess;
bonding a second chip to the first chip, wherein the second chip comprises a main portion and a conductive pillar connected to the main portion, and the conductive pillar is in the hole after the second chip is bonded to the first chip; and
removing a bottom portion of the glass substrate to expose the conductive pillar and the first chip.

12. The method for forming the chip package structure as claimed in claim 11, wherein the conductive pillar is spaced apart from the glass substrate.

13. The method for forming the chip package structure as claimed in claim 12, further comprising:
forming a molding layer in the recess, the hole, and over the glass substrate after the second chip is bonded to the first chip, wherein the molding layer surrounds the first chip and the second chip.

14. The method for forming the chip package structure as claimed in claim 13, wherein the molding layer surrounds the conductive pillar, and the molding layer separates the conductive pillar from the glass substrate.

15. The method for forming the chip package structure as claimed in claim 13, wherein the molding layer has a first portion and a second portion, the first portion is in the hole, the second portion is in the recess, and a first bottom surface of the first portion and a second bottom surface of the second portion are exposed after the bottom portion of the glass substrate is removed.

16. A chip package structure, comprising:
a glass substrate;
a conductive pillar in the glass substrate;
a first chip in the glass substrate adjacent to the conductive pillar; and
a second chip over the first chip.

17. The chip package structure as claimed in claim 16, further comprising:
a first molding layer in the glass substrate and surrounding the first chip.

18. The chip package structure as claimed in claim 17, further comprising:
a second molding layer over the glass substrate and surrounding the second chip.

19. The chip package structure as claimed in claim 16, wherein the conductive pillar protrudes from a top surface of the glass substrate.

20. The chip package structure as claimed in claim 19, further comprising:
a molding layer in the glass substrate and surrounding the conductive pillar.
